(19) United States
(12) Patent Application Publication
(10) Pub. No.: US 2022/0392905 A1
(43) Pub. Date: Dec. 8, 2022

(54) ONE-TIME PROGRAMMABLE MEMORY DEVICE AND METHOD FOR FABRICATING THE SAME

(71) Applicant: UNITED MICROELECTRONICS CORP., Hsin-Chu City (TW)

(72) Inventors: Kuo-Hsing Lee, Hsinchu County (TW); Chun-Hsien Lin, Tainan City (TW); Chih-Wei Yang, Tainan City (TW); Chang-Chien Wong, Tainan City (TW); Te-Wei Yeh, Taichung City (TW); Sheng-Yuan Hsueh, Tainan City (TW)

(73) Assignee: UNITED MICROELECTRONICS CORP., Hsin-Chu City (TW)

(21) Appl. No.: 17/363,015

(22) Filed: Jun. 30, 2021

(30) Foreign Application Priority Data
Jun. 3, 2021 (CN) 202110618587.2

(51) Int. Cl. H01L 27/112

(52) U.S. Cl. CPC H01L 27/11206

(57) ABSTRACT

A method for fabricating an one time programmable (OTP) device includes the steps of: forming a first gate structure and a second gate structure extending along a first direction on a substrate; forming a diffusion region adjacent to two sides of the first gate structure and the second gate structure; forming a silicide layer adjacent to the first gate structure; and patterning the first gate structure for forming a third gate structure and a fourth gate structure.

### BACKGROUND OF THE INVENTION

### 1. Field of the Invention

The invention relates to an one-time programmable (OTP) memory device, and more particularly to an OTP memory device including metal gate.

### 2. Description of the Prior Art

Semiconductor memory devices including non-volatile memory devices have been widely used in various electronic devices such as cellular phones, digital cameras, personal digital assistants (PDAs), and other applications. Typically, non-volatile memory devices include multi-time programmable (MTP) memory devices and one-time programmable (OTP) memory devices. In contrast to rewritable memories, OTP memory devices have the advantage of low fabrication cost and easy storage. However, OTP memory devices could only perform a single data recording action such that when certain memory cells of a destined storage block were stored with a writing program, those memory cells could not be written again.

Since current OTP memory devices still have the disadvantage of weak reading current and longer stress time under program mode, how to improve the current architecture for OTP memory devices has become an important task in this field.

### SUMMARY OF THE INVENTION

According to an embodiment of the present invention, a method for fabricating an one time programmable (OTP) memory device includes the steps of: forming a first gate structure and a second gate structure extending along a first direction on a substrate; forming a diffusion region adjacent to two sides of the first gate structure and the second gate structure; forming a silicide layer adjacent to the first gate structure; and patterning the first gate structure for forming a third gate structure and a fourth gate structure.

According to another aspect of the present invention, an one time programmable (OTP) memory device having a first shallow trench isolation (STI) and a second STI in a substrate, a first gate structure disposed on the first STI and the substrate, and a second gate structure disposed on the second STI and the substrate. Preferably, no silicide layer is disposed between the first gate structure and the second gate structure.

According to yet another aspect of the present invention, an one time programmable (OTP) memory device having a first shallow trench isolation (STI) and a second STI in a substrate, a diffusion break structure disposed between the first STI and the second STI, a first gate structure disposed on the first STI, the substrate, and the diffusion break structure, and a second gate structure disposed on the second STI, the substrate, and the diffusion break structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a block diagram of a semiconductor device according to an embodiment of the present invention.

FIGS. 2-5 illustrate a method for fabricating a semiconductor device according to an embodiment of the present invention.

FIGS. 6-9 illustrate a method for fabricating a semiconductor device according to an embodiment of the present invention.

### DETAILED DESCRIPTION

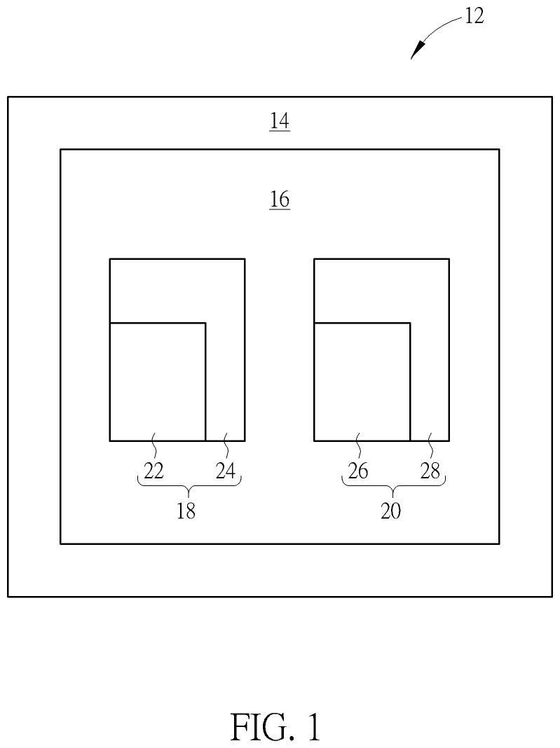

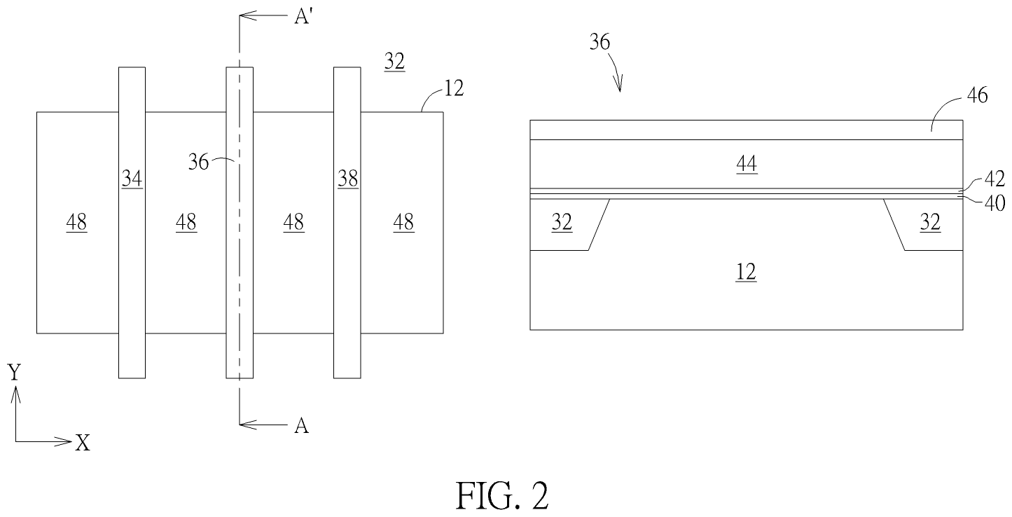

Referring to FIGS. 1-5, FIGS. 1-5 illustrate a method for fabricating a semiconductor device according to an embodiment of the present invention, in which FIG. 1 illustrates a block diagram of the semiconductor device and FIGS. 2-5 are top views and cross-section views illustrating a method for fabricating the semiconductor device in an OTP capacitor region. As shown in FIG. 1, a substrate 12 such as a silicon substrate or silicon-on-insulator (SOI) substrate is provided and an input/output (I/O) region 14, a core region 16, an one time programmable (OTP) capacitor region 18, and a static random access memory (SRAM) region 20 are defined on the substrate 12, in which the OTP capacitor region 18 further includes a cell region 22 and a periphery region 24 and the SRAM region 20 also includes a cell region 26 and a periphery region 28.

In this embodiment, metal-oxide semiconductor (MOS) transistors are preferably formed on the I/O region 14 and the core region 16 while integrated structures including MOS transistor and OTP capacitor are formed on the OTP capacitor region 18. It should also be noted that since the present invention pertains to patterning gate structure of source line in the OTP capacitor region 18 after forming silicide layer, elements on the I/O region 14, core region 16, and the SRAM region 20 are not shown in the following process for the sake of brevity.

Next, referring to FIG. 2, in which left side of FIG. 2 is a top view illustrating a method for fabricating the semiconductor device according to an embodiment of the present invention and right side of FIG. 2 is a cross-section view taken along the sectional line AA′ of the left side. As shown in FIG. 2, a shallow trench isolation (STI) 32 is formed in the substrate 12 on the OTP capacitor region 18, and an ion implantation process is conducted to implant n-type or p-type dopants into the substrate 12 for forming well regions.

Next, a plurality of gate structures 34, 36, 38 are formed on the substrate 12. As shown in the top view on the left side, each of the gate structures 34, 36, 38 are disposed extending along a first direction such as Y-direction, in which the gate structure 36 in the middle is serving as a source line while the gate structures 34, 38 adjacent to two sides of the gate structure 36 are serving as word lines. In this embodiment, the formation of the gate structures 34, 36, 38 could be accomplished by a gate first process, a high-k first approach from gate last process, or a high-k last approach from gate last process. Since this embodiment pertains to a high-k first approach, a gate dielectric layer 40 or interfacial layer made of silicon oxide, silicon oxynitride (SiON), silicon oxycarbide (SiOC), or silicon oxyfluoride (SiOF), a high-k dielectric layer 42, a gate material layer 44 made of polysilicon, and a selective hard mask 46 could be formed sequentially on the substrate 12, and a pattern transfer process is then conducted by using a patterned resist (not shown) as mask to remove part of the hard mask 46, part of the gate material layer 44, part of the high-k dielectric layer 42, and part of the gate dielectric layer 40 through single or multiple etching processes. After stripping the patterned resist, gate structures 34, 36, 38 each composed of a patterned gate dielectric layer 40, a patterned high-k dielectric layer 42, a patterned gate material layer 44, and a patterned hard mask 46 are formed on the substrate 12.

In this embodiment, the high-k dielectric layer 42 is preferably selected from dielectric materials having dielectric constant (k value) larger than 4. For instance, the high-k dielectric layer 42 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

Next, at least a spacer (not shown) is formed on the sidewalls of each of the gate structures 34, 36, 38 and then a diffusion region 48 or source/drain regions are formed in the substrate 12 adjacent to one side or two sides of the gate structures 34, 36, 38. In this embodiment, the spacer could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The diffusion region 48 or source/drain regions could include n-type dopants or p-type dopants depending on the type of device being fabricated.

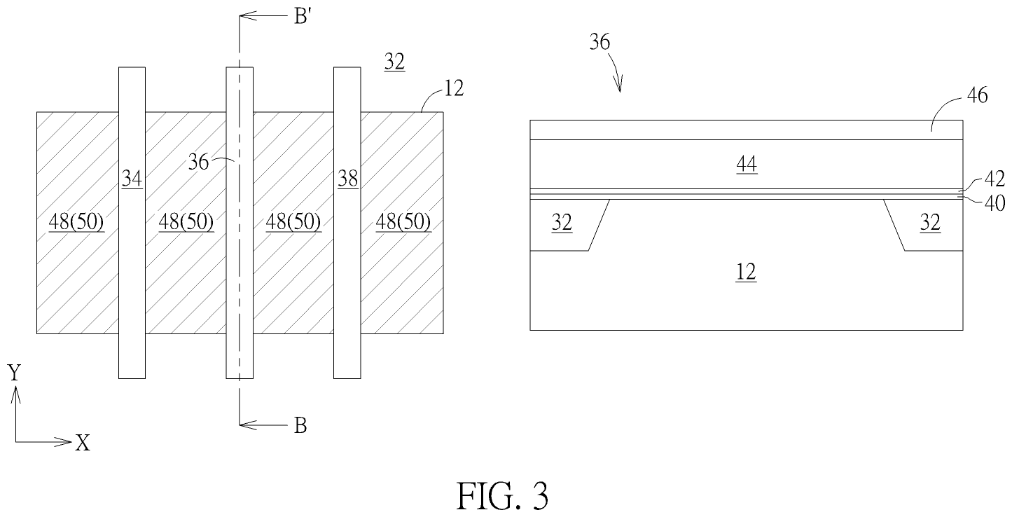

Next, referring to FIG. 3, in which left side of FIG. 3 is a top view illustrating a method for fabricating the semiconductor device following FIG. 2 according to an embodiment of the present invention and right side of FIG. 3 is a cross-section view taken along the sectional line BB′ of the left side. As shown in FIG. 3, a salicide process could be conducted to form a silicide layer 50 on the surface of the substrate 12 adjacent to two sides of the gate structures 34, 36, 38. It should be noted that at this stage the source line or the gate structure 36 in the center has not been patterned into two portions yet and the hard mask 46 is still disposed on top of the gate electrode or gate material layer 44 made of polysilicon, the silicide layer 50 is only disposed on the surface of the substrate 12 adjacent to two sides of the gate structures 34, 36, 38 but not directly on top of the gate structures 34, 36, 38.

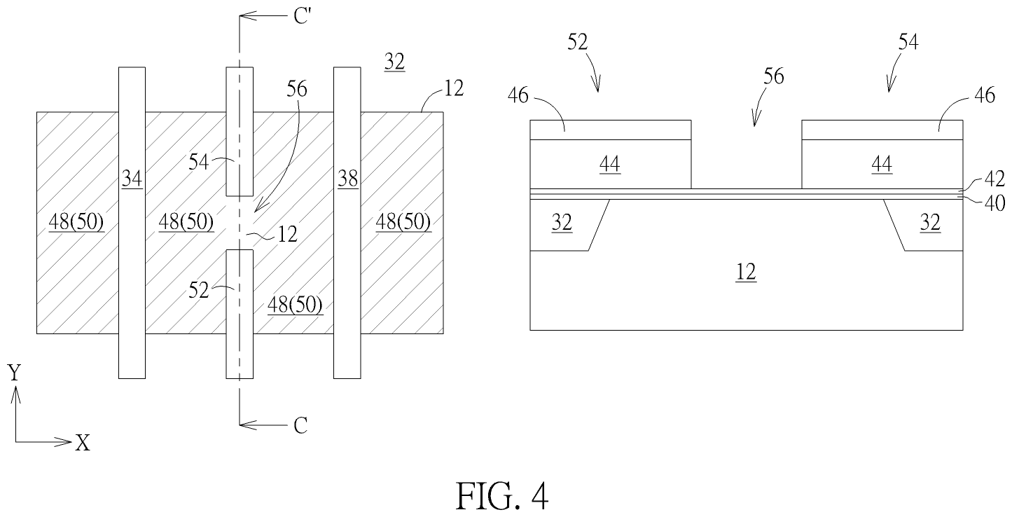

Next, referring to FIG. 4, in which left side of FIG. 4 is a top view illustrating a method for fabricating the semiconductor device following FIG. 3 according to an embodiment of the present invention and right side of FIG. 4 is a cross-section view taken along the sectional line CC′ of the left side. As shown in FIG. 4, a pattern transfer process is conducted to pattern the gate structure 36 or source line to form a gate structure 52 and a gate structure 54. Specifically, the pattern transfer process could be accomplished by first forming a patterned mask (not shown) such as a patterned resist extending along a second direction (such as X-direction) to cover part of the gate structure 36, and then conducting an etching process by using the patterned mask as mask to remove part of the gate structure 36 for dividing the gate structure 36 into two portions including the gate structure 52 on the bottom and the gate structure 54 on the top, and at the same time forming a recess 56 between the gate structures 52, 54. It should be noted that since silicide layer 50 has been formed adjacent to two sides of the gate structure 36 before the gate structure 36 is divided, the recess 56 formed afterwards between the gate structures 52, 54 on the left side of FIG. 4 preferably exposes the surface of the substrate 12 instead of the silicide layer 50.

It should also be noted that even though the gate dielectric layer 40 and high-k dielectric layer 42 are kept on the surface of the substrate 12 between the ends of two gate structures 52, 54 after patterning the gate structure 36 as shown on the right side of FIG. 4, according to other embodiment of the present invention, it would also be desirable to completely remove the gate dielectric layer 40 and high-k dielectric layer 42 between ends of the gate structures 52, 54 and expose the surface of the substrate 12 during the patterning of gate structure 36, which is also within the scope of the present invention.

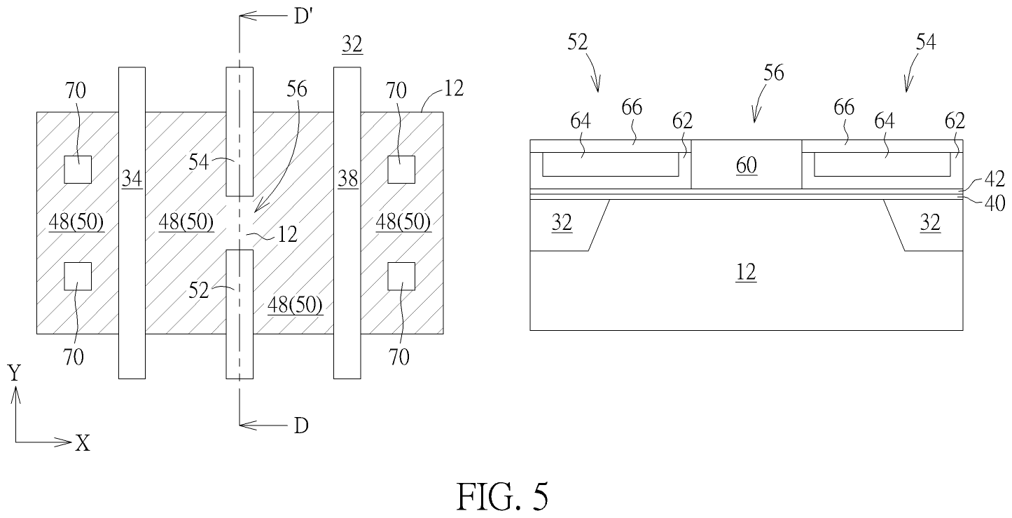

Next, referring to FIG. 5, in which left side of FIG. 5 is a top view illustrating a method for fabricating the semiconductor device following FIG. 4 according to an embodiment of the present invention and right side of FIG. 5 is a cross-section view taken along the sectional line DD′ of the left side. As shown in FIG. 5, an interlayer dielectric (ILD) layer 60 made of silicon oxide is then formed on the gate structures 34, 38, 52, 54 and the STI 32, and a planarizing process such as chemical mechanical polishing (CMP) process is conducted to remove part of the ILD layer 60 and the hard mask 46 to expose the gate material layers 44 made of polysilicon so that the top surfaces of the gate material layers 44 and the ILD layer 60 are coplanar.

Next, a replacement metal gate (RMG) process is conducted to transform the gate structures 34, 38, 52, 54 into metal gates. For instance, the RMG process could be accomplished by first conducting a selective dry etching or wet etching process using etchants including but not limited to for example ammonium hydroxide (NH₄OH) or tetramethylammonium hydroxide (TMAH) to remove the gate material layers 44 from gate structures 34, 38, 52, 54 for forming recesses (not shown) in the ILD layer 60. Next, conductive layers including a work function metal layer 62 and a low resistance metal layer 64 are formed in each of the recesses, and a planarizing process such as CMP is conducted to remove part of low resistance metal layer 64 and part of work function metal layer 62 so that the top surfaces of the U-shaped work function metal layer 62, the low resistance metal layer 64, and the ILD layer 60 are coplanar.

In this embodiment, the work function metal layer 62 is formed for tuning the work function of the metal gate in accordance with the conductivity of the device. For an NMOS transistor, the work function metal layer 62 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 62 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 62 and the low resistance metal layer 64, in which the material of the barrier layer may include titanium (Ti), titanium nitride (TiN), tantalum (Ta) or tantalum nitride (TaN). Furthermore, the material of the low-resistance metal layer 64 may include copper (Cu), aluminum (Al), titanium aluminum (TiAl), cobalt tungsten phosphide (CoWP) or any combination thereof. Next, part of the work function metal layer 62 and part of the low resistance metal layer 64 are removed to form recesses (not shown), and a hard mask 66 is then formed into each of the recesses so that the top surfaces of the hard masks 66 and the ILD layer 60 are coplanar. The hard mask 66 could be made of material including but not limited to for example SiO₂, SiN, SiON, SiCN, or combination thereof.

Next, another ILD layer (not shown) could be formed on the gate structures 34, 38, 52, 54 and the ILD layer 60, and a photo-etching process is conducted by using a patterned mask (not shown) as mask to remove part of the newly formed ILD layer and the ILD layer 60 adjacent to the gate structures 34, 38 for forming contact holes (not shown) exposing the diffusion regions 48. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned conductive materials for forming contact plugs 70 directly contacting the diffusion regions 48. This completes the fabrication of a semiconductor device according to an embodiment of the present invention.

Referring again to FIG. 5, FIG. 5 illustrates a structural view of an OTP device according to an embodiment of the present invention. As shown in the top view section on left side of FIG. 5, the OTP device preferably includes gate structures 52, 54 extending along Y-direction on the substrate 12, a gate structure 34 extending along the same Y-direction adjacent to one side of the gate structures 52, 54, a gate structure 38 extending along the Y-direction adjacent to another side of the gate structures 52, 54, a diffusion region 48 and silicide layer 50 disposed on the substrate 12 adjacent to two sides of the gate structures 34, 38, 52, 54, and a STI 32 surrounding the diffusion region 48.

As shown in the cross-section view on right side of FIG. 5, the OTP device further includes a first STI such as the STI 32 on the left and a second STI such as the STI 32 on the right within the substrate 12, in which the gate structure 52 is disposed on the STI 32 on the left and the substrate 12 while the gate structure 54 is disposed on the STI 32 on the right and the substrate 12. It should be noted that even though the silicide layer 50 is disposed on the substrate 12 adjacent to two sides of the gate structures 52, 54, no silicide layer 50 is disposed between two ends of the gate structures 52, 54 in this embodiment. In other words, as shown in the top view portion on left side of FIG. 5, edges of the silicide layer 50 are aligning edges of the gate structures 52, 54 along Y-direction without extending to the region between the two ends of the gate structures 52, 54 as the region between ends of the gate structures 52, 54 is the substrate 12 surface instead of the silicide layer 50.

Moreover, despite a high-k first approach is conducted for fabricating metal gate transistors in this embodiment, according to other embodiment of the present invention, it would also be desirable to conduct a high-k last approach for fabricating metal gate structures and in such instance, the gate structures 52, 54 shown in right portion of FIG. 5 would include U-shape high-k dielectric layer between the U-shape work function metal layer 62 and the substrate 12, which is also within the scope of the present invention.

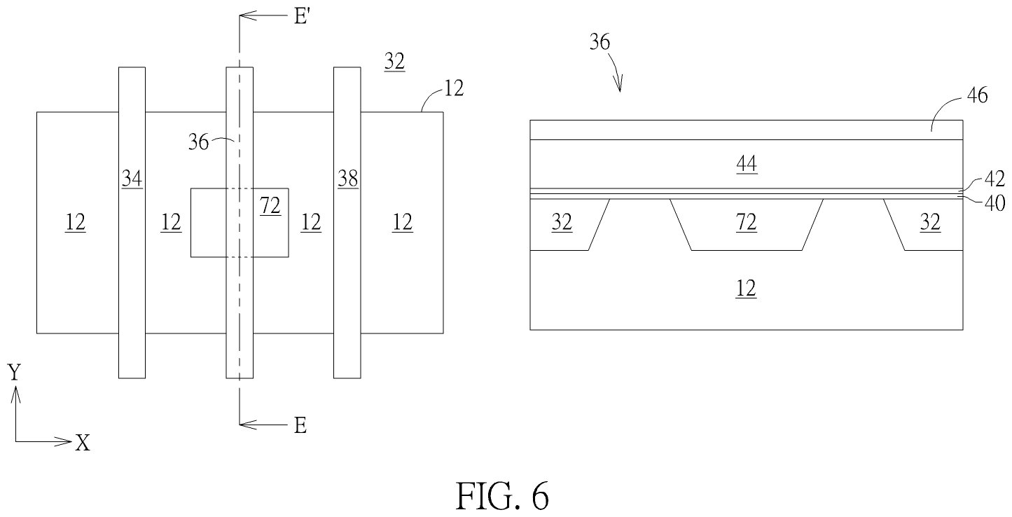

Referring to FIGS. 6-9, FIGS. 6-9 are top views and cross-section views illustrating a method for fabricating the semiconductor device on an OTP capacitor region according to an embodiment of the present invention. Referring to FIG. 6, in which left side of FIG. 6 is a top view illustrating a method for fabricating the semiconductor device according to an embodiment of the present invention and right side of FIG. 6 is a cross-section view taken along the sectional line EE′ of the left side. As shown in FIG. 6, a STI 32 and a diffusion break structure 72 are formed in the substrate 12 on the OTP capacitor region 18 and then an ion implantation process is conducted to implant n-type or p-type dopants into the substrate 12 for forming well regions.

It should be noted that the formation of the diffusion break structure 72 could be accomplished by first forming a patterned mask (not shown) on the substrate 12, conducting an etching process by using the patterned mask as mask to remove part of the substrate 12 for forming a recess extending along a direction perpendicular to the direction of gate structures (not shown) afterwards, and then forming a dielectric material such as silicon oxide or silicon nitride into the recess for forming the diffusion break structure 72. In this embodiment, the STI 32 and the diffusion break structure 72 could be fabricated by same or different process and the STI 32 and the diffusion break structure 72 could also be made of same or different materials, which are all within the scope of the present invention. Since the fabrication of STI and diffusion break structures is well known to those skilled in the art, the details of which are not explained herein for the sake of brevity.

Next, a plurality of gate structures 34, 36, 38 are formed on the substrate 12. As shown in the top view on the left side of FIG. 6, each of the gate structures 34, 36, 38 are disposed extending along a first direction such as Y-direction while the diffusion break structure 72 is disposed extending along a second direction such as X-direction, in which the gate structure 36 is disposed directly on top of the diffusion break structure 72, the gate structure 36 in the middle is serving as a source line while the gate structures 34, 38 adjacent to two sides of the gate structure 36 are serving as word lines. Similar to the aforementioned embodiment, the formation of the gate structures 34, 36, 38 could be accomplished by a gate first process, a high-k first approach from gate last process, or a high-k last approach from gate last process. Since this embodiment pertains to a high-k first approach, a gate dielectric layer 40 or interfacial layer made of silicon oxide, silicon oxynitride (SiON), silicon oxycarbide (SiOC), or silicon oxyfluoride (SiOF), a high-k dielectric layer 42, a gate material layer 44 made of polysilicon, and a selective hard mask 46 could be formed sequentially on the substrate 12, and a pattern transfer process is then conducted by using a patterned resist (not shown) as mask to remove part of the hard mask 46, part of the gate material layer 44, part of the high-k dielectric layer 42, and part of the gate dielectric layer 40 through single or multiple etching processes. After stripping the patterned resist, gate structures 34, 36, 38 each composed of a patterned gate dielectric layer 40, a patterned high-k dielectric layer 42, a patterned gate material layer 44, and a patterned hard mask 46 are formed on the substrate 12.

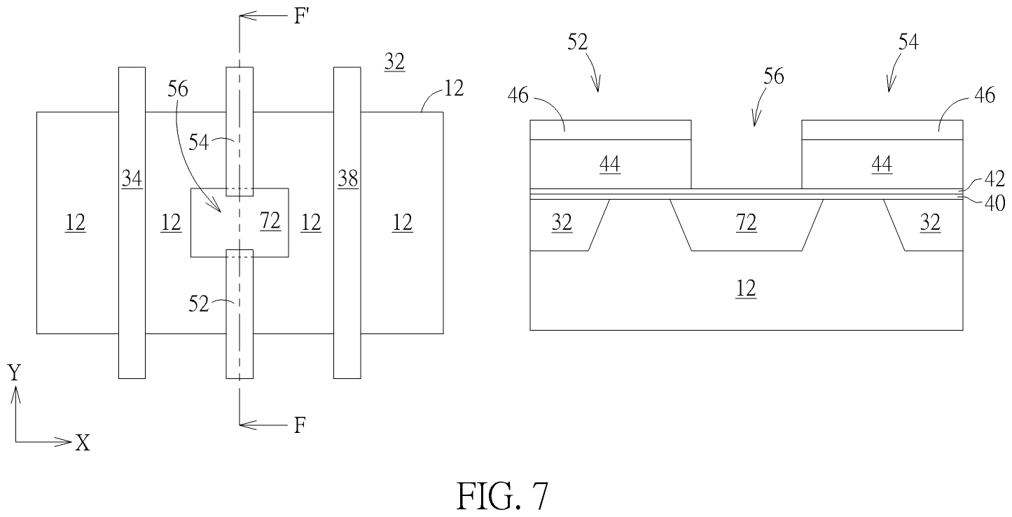

Next, referring to FIG. 7, in which left side of FIG. 7 is a top view illustrating a method for fabricating the semiconductor device following FIG. 6 according to an embodiment of the present invention and right side of FIG. 7 is a cross-section view taken along the sectional line FF′ of the left side. As shown in FIG. 7, a pattern transfer process is conducted to pattern the gate structure 36 or source line to form a gate structure 52 and a gate structure 54. Specifically, the pattern transfer process could be accomplished by first forming a patterned mask (not shown) such as a patterned resist extending along a second direction (such as X-direction) to cover part of the gate structure 36, and then conducting an etching process by using the patterned mask as mask to remove part of the gate structure 36 for dividing the gate structure 36 into two portions including the gate structure 52 on the bottom and the gate structure 54 on the top, and at the same time forming a recess 56 between the gate structures 52, 54 for exposing the diffusion break structure 72. Similar to the aforementioned embodiment, even though the gate dielectric layer 40 and high-k dielectric layer 42 are kept on the surface of the substrate 12 between the two ends of the gate structures 52, 54 after patterning the gate structure 36, according to other embodiment of the present invention, it would also be desirable to completely remove the gate dielectric layer 40 and high-k dielectric layer 42 between the ends of the gate structures 52, 54 and expose the surface of the diffusion break structure 72 during the patterning of gate structure 36, which is also within the scope of the present invention.

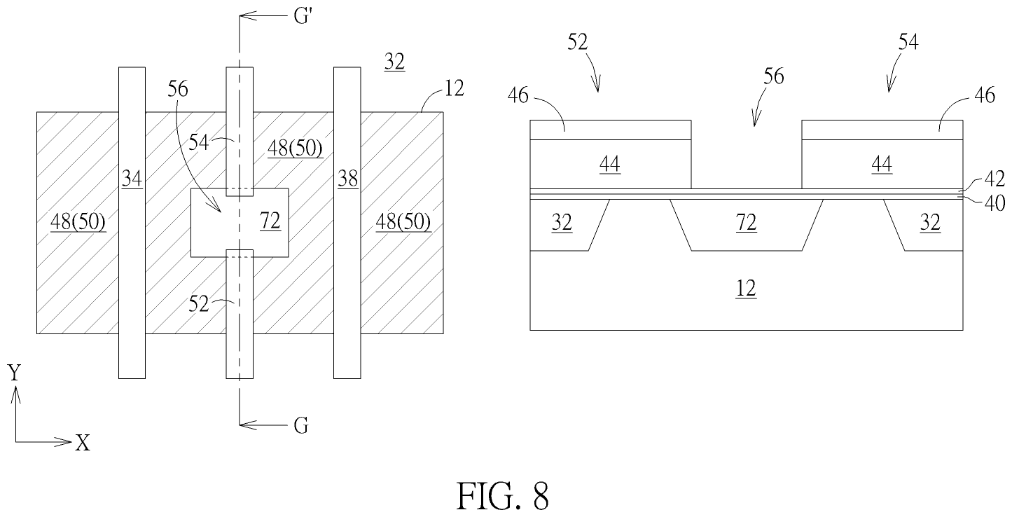

Next, referring to FIG. 8, in which left side of FIG. 8 is a top view illustrating a method for fabricating the semiconductor device following FIG. 7 according to an embodiment of the present invention and right side of FIG. 8 is a cross-section view taken along the sectional line GG′ of the left side. As shown in FIG. 8, at least a spacer (not shown) is formed on the sidewalls of each of the gate structures 34, 38, 52, 54 and then a diffusion region 48 or source/drain regions are formed in the substrate 12 adjacent to one side or two sides of the gate structures 34, 38, 52, 54. In this embodiment, the spacer could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The diffusion region 48 or source/drain regions could include n-type dopants or p-type dopants depending on the type of device being fabricated.

Next, a salicide process could be conducted to form a silicide layer 50 on the surface of the substrate 12 adjacent to two sides of the gate structures 34, 38, 52, 54. It should be noted that since the source line in the middle has already been patterned into two portions including the gate structures 52, 54 and a diffusion break structure 72 is disposed in the substrate 12 between the gate structures 52, 54 at this stage, the top surface of the diffusion break structure 72 between the two ends of gate structures 52, 54 would not react with metal to form a silicide layer as the silicide layer 50 is only formed on the surface of the substrate 12 adjacent to two sides of the source line and the word lines.

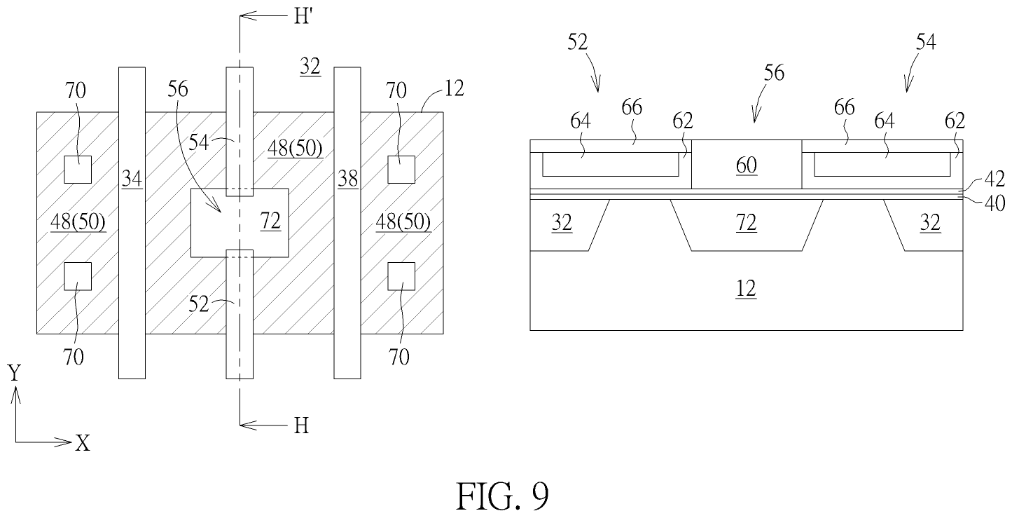

Next, referring to FIG. 9, in which left side of FIG. 9 is a top view illustrating a method for fabricating the semiconductor device following FIG. 8 according to an embodiment of the present invention and right side of FIG. 9 is a cross-section view taken along the sectional line HH′ of the left side. As shown in FIG. 9, an interlayer dielectric (ILD) layer 60 made of silicon oxide is then formed on the gate structures 34, 38, 52, 54 and the STI 32, and a planarizing process such as chemical mechanical polishing (CMP) process is conducted to remove part of the ILD layer 60 and the hard mask 46 to expose the gate material layers 44 made of polysilicon so that the top surfaces of the gate material layers 44 and the ILD layer 60 are coplanar.

Next, a replacement metal gate (RMG) process is conducted to transform the gate structures 34, 38, 52, 54 into metal gates. For instance, the RMG process could be accomplished by first conducting a selective dry etching or wet etching process using etchants including but not limited to for example ammonium hydroxide (NH₄OH) or tetramethylammonium hydroxide (TMAH) to remove the gate material layers 44 from gate structures 34, 38, 52, 54 for forming recesses (not shown) in the ILD layer 60. Next, conductive layers including a work function metal layer 62 and a low resistance metal layer 64 are formed in each of the recesses, and another planarizing process such as CMP is conducted to remove part of low resistance metal layer 64 and part of work function metal layer 62 so that the top surfaces of the U-shaped work function metal layer 62, the low resistance metal layer 64, and the ILD layer 60 are coplanar. Next, part of the work function metal layer 62 and part of the low resistance metal layer 64 are removed to form recesses (not shown), and a hard mask 66 is then formed into each of the recesses so that the top surfaces of the hard masks 66 and the ILD layer 60 are coplanar. The hard mask 66 could be made of material including but not limited to for example SiO₂, SiN, SiON, SiCN, or combination thereof.

Next, another ILD layer (not shown) could be formed on the gate structures 34, 38, 52, 54 and the ILD layer 60, and a photo-etching process is conducted by using a patterned mask (not shown) as mask to remove part of the newly formed ILD layer and the ILD layer 60 adjacent to the gate structures 34, 38 for forming contact holes (not shown) exposing the diffusion regions 48. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned conductive materials for forming contact plugs 70 directly contacting the diffusion regions 48. This completes the fabrication of a semiconductor device according to an embodiment of the present invention.

Referring again to FIG. 9, FIG. 9 illustrates a structural view of an OTP device according to an embodiment of the present invention. As shown in the top view section on left side of FIG. 9, the OTP device preferably includes gate structures 52, 54 extending along Y-direction on the substrate 12, a gate structure 34 extending along the same Y-direction adjacent to one side of the gate structures 52, 54, a gate structure 38 extending along the Y-direction adjacent to another side of the gate structures 52, 54, a diffusion region 48 and silicide layer 50 disposed on the substrate 12 adjacent to two sides of the gate structures 34, 38, 52, 54, a STI 32 surrounding the diffusion region 48, and a diffusion break structure 72 disposed between the gate structures 52, 54.

As shown in the cross-section view on right side of FIG. 9, the OTP device further includes a first STI such as the STI 32 on the left and a second STI such as the STI 32 on the right within the substrate 12, in which the gate structure 52 is disposed on the STI 32 on the left, the substrate 12, and the diffusion break structure 72 while the gate structure 54 is disposed on the STI 32 on the right, the substrate 12, and the diffusion break structure 72. It should be noted that even though the silicide layer 50 is disposed on the substrate 12 adjacent to two sides of the gate structures 52, 54, no silicide layer 50 is disposed between two ends of the gate structures 52, 54 on the diffusion break structure 72 in this embodiment.

Similar to the aforementioned embodiment, despite a high-k first approach is conducted for fabricating metal gate transistors in this embodiment, according to other embodiment of the present invention, it would also be desirable to conduct a high-k last approach for fabricating metal gate structures and in such instance, the gate structures 52, 54 shown in right portion of FIG. 9 would include U-shape high-k dielectric layer between the U-shape work function metal layer 62 and the substrate 12, which is also within the scope of the present invention.

Typically, a patterning or photo-etching process is conducted to divide the source line into two portions such as the gate structures prior to the formation of silicide layer in current fabrication of OTP memory device. Since the surface of the substrate or diffusion region between two ends of the separated source line or gate structures is exposed before the salicide process, a silicide layer would be formed on the surface of the diffusion region not only adjacent to two sides of the source line but also between two ends of the divided source lines during the salicide process. The formation of the silicide layer particularly between the two ends of the divided source lines however would easily affect performance of the OTP memory device. To resolve this issue, the present invention preferably forms a silicide layer on the diffusion region adjacent to two sides of the source line and then conducts a pattern transfer process to divide the source line into two portions such as the gate structures 52, 54 disclosed in the aforementioned embodiment shown in FIGS. 2-5. By doing so no silicide layer would then be formed on the surface of the substrate between two ends of the divided gate structures 52, 54.

Moreover, according to another approach of the present invention, it would also be desirable to first form a STI in the substrate along with a diffusion break structure at the place where source line would be divided into gate structures 52, 54 as shown in FIG. 6. By using the diffusion break structure as an insulating blockade between two ends of the divided source lines or gate structures 52, 54, no silicide layer would be formed on the particular region or substrate between two ends of the divided source lines whether the source line is divided before or after the salicide process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating an one time programmable (OTP) memory device, comprising:
forming a first gate structure and a second gate structure extending along a first direction on a substrate;
forming a diffusion region adjacent to two sides of the first gate structure and the second gate structure;
forming a silicide layer adjacent to the first gate structure; and
patterning the first gate structure for forming a third gate structure and a fourth gate structure.

2. The method of claim 1, further comprising:
forming the first gate structure, the second gate structure, and a fifth gate structure extending along the first direction;
forming the diffusion region adjacent to two sides of the first gate structure, the second gate structure, and the fifth gate structure; and
forming the silicide layer adjacent to two sides of the first gate structure, the second gate structure, and the fifth gate structure.

3. The method of claim 2, further comprising:
performing a replacement metal gate (RMG) process to transform the second gate structure, the third gate structure, the fourth gate structure, and the fifth gate structure into metal gates.

4. The method of claim 2, wherein each of the first gate structure, the second gate structure, and the fifth gate structure comprises:
a gate dielectric layer on the substrate;
a gate material layer on the gate dielectric layer; and
a hard mask on the gate material layer.

5. The method of claim 4, wherein the step of patterning the first gate structure comprises:
removing the hard mask and the gate material for forming a recess between the third gate structure and the fourth gate structure.

6. An one time programmable (OTP) memory device, comprising:
a first shallow trench isolation (STI) and a second STI in a substrate;
a first gate structure disposed on the first STI and the substrate; and
a second gate structure disposed on the second STI and the substrate, wherein no silicide layer is disposed between the first gate structure and the second gate structure.

7. The OTP memory device of claim 6, wherein the first gate structure and the second gate structure are disposed extending along a first direction on the substrate.

8. The OTP memory device of claim 7, further comprising:
a third gate structure disposed extending along the first direction on one side of the first gate structure; and
a fourth gate structure disposed extending along the first direction on another side of the first gate structure.

9. The OTP memory device of claim 8, further comprising a silicide layer disposed between the first gate structure and the third gate structure.

10. The OTP memory device of claim 8, further comprising a silicide layer disposed between the first gate structure and the fourth gate structure.

11. An one time programmable (OTP) memory device, comprising:
a first shallow trench isolation (STI) and a second STI in a substrate;
a diffusion break structure disposed between the first STI and the second STI;
a first gate structure disposed on the first STI, the substrate, and the diffusion break structure; and
a second gate structure disposed on the second STI, the substrate, and the diffusion break structure.

12. The OTP memory device of claim 11, wherein the first gate structure and the second gate structure are disposed extending along a first direction on the substrate.

13. The OTP memory device of claim 12, further comprising:
a third gate structure disposed extending along the first direction on one side of the first gate structure; and
a fourth gate structure disposed extending along the first direction on another side of the first gate structure.

14. The OTP memory device of claim 13, further comprising a silicide layer disposed between the first gate structure and the third gate structure.

15. The OTP memory device of claim 13, further comprising a silicide layer disposed between the first gate structure and the fourth gate structure.
